(19) United States
(12) Patent Application Publication
(10) Pub. No.: US 2026/0026135 A1
(43) Pub. Date: Jan. 22, 2026

(54) SEMICONDUCTOR PACKAGE AND SEMICONDUCTOR PACKAGE MANUFACTURING METHOD

(71) Applicant: Samsung Electronics Co., Ltd., Suwon-si (KR)

(72) Inventor: Dusik Jung, Suwon-si (KR)

(73) Assignee: Samsung Electronics Co., Ltd., Suwon-si (KR)

(21) Appl. No.: 18/968,370

(22) Filed: Dec. 4, 2024

(30) Foreign Application Priority Data
Jul. 18, 2024 (KR) 10-2024-0094817

(51) Int. Cl. H10F 77/60; H10F 39/00

(52) U.S. Cl. CPC H10F 77/60; H10F 39/804; H10F 39/811

(57) ABSTRACT

Described herein are semiconductor packages with improved heat dissipation performance from a semiconductor chip to a semiconductor substrate despite the lack of uniformity of heat generation in the semiconductor chip. The semiconductor packages described herein may be used with image sensor chips, which produce heat in a non-uniform fashion across its surface. A semiconductor package includes a semiconductor substrate having a first substrate surface defining one or more recesses, an image sensor chip arranged on the first substrate surface of the semiconductor substrate, the image sensor chip including an image sensing area and a non-sensing area, a cover glass facing an upper portion of the image sensor 10 chip, a bonding dam surrounding the image sensing area and positioned between the image sensor chip and the cover glass, and one or more heat dissipation members arranged in the one or more recesses.

### CROSS-REFERENCE TO RELATED APPLICATION

This application claims the benefit under 35 U.S.C. § 119(a)-(d) of Korean Patent Application No. 10-2024-0094817, filed on Jul. 18, 2024, in the Korean Intellectual Property Office, the entire content of which is hereby incorporated herein by reference in its entirety.

### BACKGROUND

### 1. Field of the Invention

The disclosure relates to a semiconductor package and a semiconductor package manufacturing method.

### 2. Description of the Related Art

As electronic devices become lighter and higher performing, semiconductor packages also need to be miniaturized and higher performing. To implement miniaturized, light, high-performance, large-capacity, and high-reliability semiconductor packages, research and development on semiconductor packages with a structure in which semiconductor chips are stacked in multiple levels are continuously being conducted. The above description is information the inventor(s) acquired during the course of conceiving the present disclosure, or already possessed at the time, and is not necessarily art publicly known before the present application was filed.

### SUMMARY

The technical goal to be achieved through the present disclosure is to provide a semiconductor package with improved heat dissipation performance from a semiconductor chip to a semiconductor substrate despite the lack of uniformity of heat generation in the semiconductor chip.

The technical goal to be achieved through the present disclosure is to provide a semiconductor package for reducing the temperature variations between portions of the semiconductor package due to the difference in heat generation between different portions of a semiconductor chip.

In one non-limiting example, aspects of the present disclosure may be applied to image sensor chips, which produce heat in a non-uniform fashion across its surface. This may be due to a variety of reasons, including for example the presence of hotspots in correspondence with regions where electrical current is the highest. Certain portions of the image sensing area (e.g., amplifiers) may consume significant amounts of power, thereby locally increasing heat generation. The semiconductor packages described herein reduce temperature variations arising in image sensor chips.

However, the goals to be achieved through the present disclosure are not limited to those described above, and additional goals not mentioned above may be clearly understood by one of ordinary skill in the art from the following description. For example, the semiconductor packages described herein can reduce temperature variations arising in semiconductor chips other than image sensor chips.

According to an aspect, there is provided a semiconductor package including a semiconductor substrate having a first substrate surface defining one or more recesses, an image sensor chip arranged on the first substrate surface of the semiconductor substrate, the image sensor chip including an image sensing area and a non-sensing area, a cover glass facing an upper portion of the image sensor chip, a bonding dam surrounding the image sensing area and positioned between the image sensor chip and the cover glass, and one or more heat dissipation members arranged in the one or more recesses.

The one or more heat dissipation members may overlap with the image sensing area of the image sensor chip.

Upper surfaces of the one or more heat dissipation members may be co-planar with the first substrate surface of the semiconductor substrate.

The image sensing area may include or more high-temperature areas that generate more heat than a remaining area defined in the image sensor chip. The one or more high-temperature areas may overlap with the one or more heat dissipation members.

The one or more heat dissipation members may be in contact with a lower portion of the image sensor chip that is opposite to the upper portion.

The one or more heat dissipation members may include a plurality of heat dissipation members having a same thickness.

The image sensing area may further include one or more low-temperature areas configured to generate less heat than a remaining area defined in the image sensor chip. At least one of the one or more high-temperature areas and at least one of the one or more low-temperature areas may overlap with one heat dissipation member.

The one or more heat dissipation members may include a first heat dissipation member arranged to overlap with a first high-temperature area of the one or more high-temperature areas, and a second heat dissipation member arranged to overlap with a second high-temperature area of the one or more high-temperature areas, the second heat dissipation member having a smaller thickness than the first heat dissipation member. The first high-temperature area may generate more heat than the second high-temperature area.

The one or more heat dissipation members may include a first heat dissipation portion having a first thickness, and a second heat dissipation portion having a second thickness smaller than the first thickness.

A portion of the image sensor chip overlapping with the first heat dissipation portion may generate more heat than a portion of the image sensor chip overlapping with the second heat dissipation portion.

The second heat dissipation portion may surround the first heat dissipation portion.

At least one heat dissipation member of the one or more heat dissipation members may be arranged on the semiconductor substrate, and the one heat dissipation member may extend over an area that overlaps with the entire image sensing area of the image sensor chip.

The at least one heat dissipation member may include one or more first heat dissipation portions having a first thickness, and a second heat dissipation portion having a second thickness smaller than the first thickness.

A portion of the image sensor chip overlapping with the first heat dissipation portion may generate more heat than a remaining area defined in the image sensor chip.

The semiconductor package may further include a redistribution layer formed in the semiconductor substrate, and a conductive wire connecting the image sensor chip to the redistribution layer of the semiconductor substrate. The one or more heat dissipation members may be electrically insulated from the redistribution layer of the semiconductor substrate.

The semiconductor package may further include a lower heat dissipation member arranged on a second substrate surface, opposite to the first substrate surface, of the semiconductor substrate, and a thermally conductive via extending through the semiconductor substrate and connecting the one or more heat dissipation members to the lower heat dissipation member.

According to an aspect, there is provided a semiconductor package including a semiconductor substrate on which a redistribution layer is formed, the semiconductor substrate having a first substrate surface defining one or more recesses, a semiconductor chip arranged on the first substrate surface of the semiconductor substrate, the semiconductor chip including a first surface opposite to the semiconductor substrate and a second surface opposite to the first surface, a conductive wire connected to the second surface of the semiconductor chip, the conductive wire electrically connecting the semiconductor chip to the redistribution layer of the semiconductor substrate, a molding member surrounding the semiconductor chip, and a first heat dissipation member arranged in the one or more recesses, the first heat dissipation member forming a heat conduction path between the semiconductor chip and the semiconductor substrate.

A portion of the semiconductor chip overlapping with the first heat dissipation member may generate more heat than a portion of the semiconductor chip non-overlapping with the first heat dissipation member.

The semiconductor package may further include a second heat dissipation member arranged in the one or more recesses. The first heat dissipation member may have a first thickness, and the second heat dissipation member may have a second thickness smaller than the first thickness. A portion of the semiconductor chip overlapping with the first heat dissipation member may generate more heat than a portion of the semiconductor chip overlapping with the second heat dissipation member.

An upper surface of the first heat dissipation member may be co-planar with the first substrate surface of the semiconductor substrate. The first heat dissipation member may be electrically insulated from the redistribution layer of the semiconductor substrate.

The semiconductor package may further include a lower heat dissipation member arranged on a second substrate surface, opposite to the first substrate surface, of the semiconductor substrate, and a thermally conductive via extending through the semiconductor substrate and connecting the one or more heat dissipation members to the lower heat dissipation member.

Additional aspects of embodiments will be set forth in part in the description which follows and, in part, will be apparent from the description, or may be learned by practice of the disclosure.

According to the present disclosure, arranging a heat dissipation member on the surface of a semiconductor substrate on which a semiconductor chip is arranged may improve the heat dissipation performance from the semiconductor chip to the semiconductor substrate and thereby reduce the temperature variations between portions of a semiconductor package. In addition, positioning a heat dissipation member on a portion of a semiconductor substrate corresponding to the main heat-generating area of a semiconductor chip may allow effective dissipation of heat generated from the main heat-generating area of the semiconductor chip to the semiconductor substrate.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1A is a plan view of an exemplary image sensor chip according to an embodiment;

FIG. 1B is a simulation result graph showing the temperature of each portion of an exemplary image sensor chip;

FIG. 2 is a cross-sectional view of a semiconductor package according to an embodiment;

FIG. 3A is an exploded perspective view of a semiconductor package according to an embodiment;

FIG. 3B is an exploded perspective view of a semiconductor package according to an embodiment;

FIG. 4A is a cross-sectional view of a semiconductor package according to an embodiment;

FIG. 4B is an exploded perspective view of a semiconductor package according to an embodiment;

FIG. 5A is a cross-sectional view of a semiconductor package according to an embodiment;

FIG. 5B is an exploded perspective view of a semiconductor package according to an embodiment;

FIG. 6A is a cross-sectional view of a semiconductor package according to an embodiment;

FIG. 6B is an exploded perspective view of a semiconductor package according to an embodiment;

FIG. 7A is a cross-sectional view of a semiconductor package according to an embodiment;

FIG. 7B is an exploded perspective view of a semiconductor package according to an embodiment;

FIG. 8 is a cross-sectional view of a semiconductor package according to an embodiment;

FIG. 9A is a cross-sectional view of a semiconductor package according to an embodiment;

FIG. 9B is a cross-sectional view of a semiconductor package according to an embodiment;

FIG. 9C is a cross-sectional view of a semiconductor package according to an embodiment; and

FIG. 9D is a cross-sectional view of a semiconductor package according to an embodiment.

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

The same name may be used to describe an element included in the embodiments described above and an element having a common function. Unless otherwise mentioned, the descriptions of the examples may be applicable to the following examples and thus, duplicated descriptions will be omitted for conciseness.

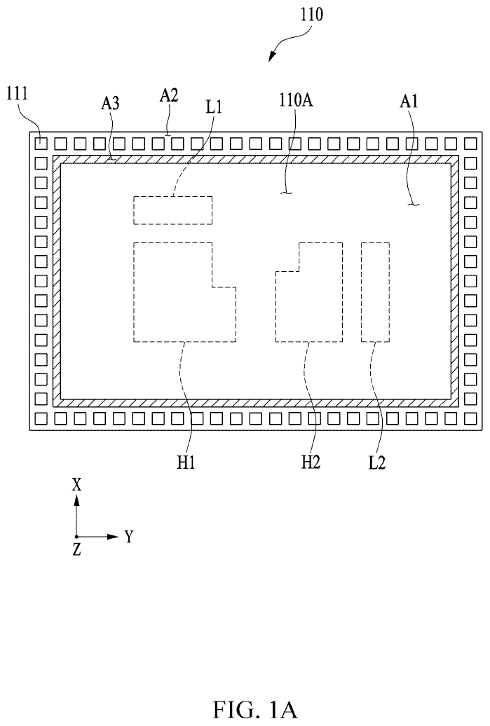

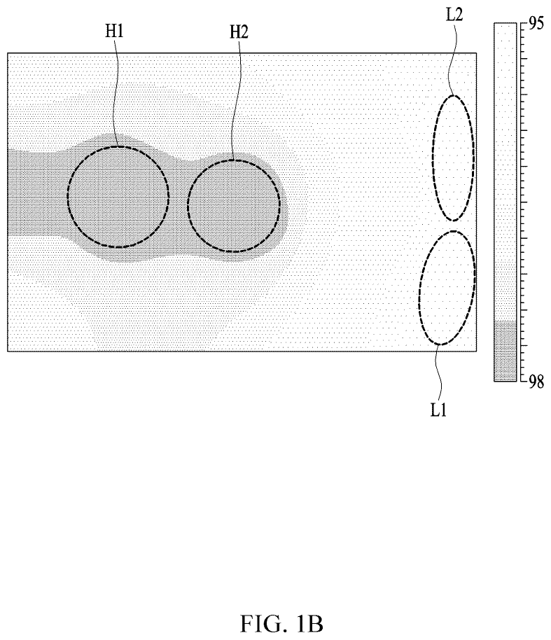

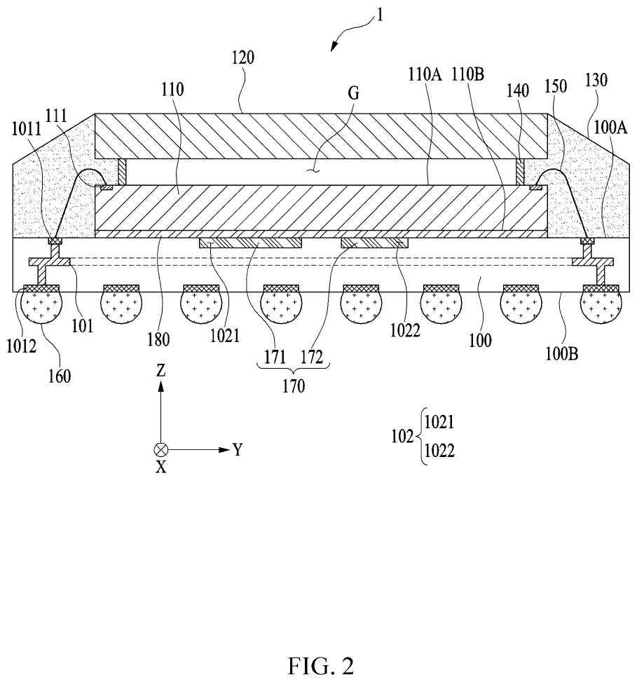

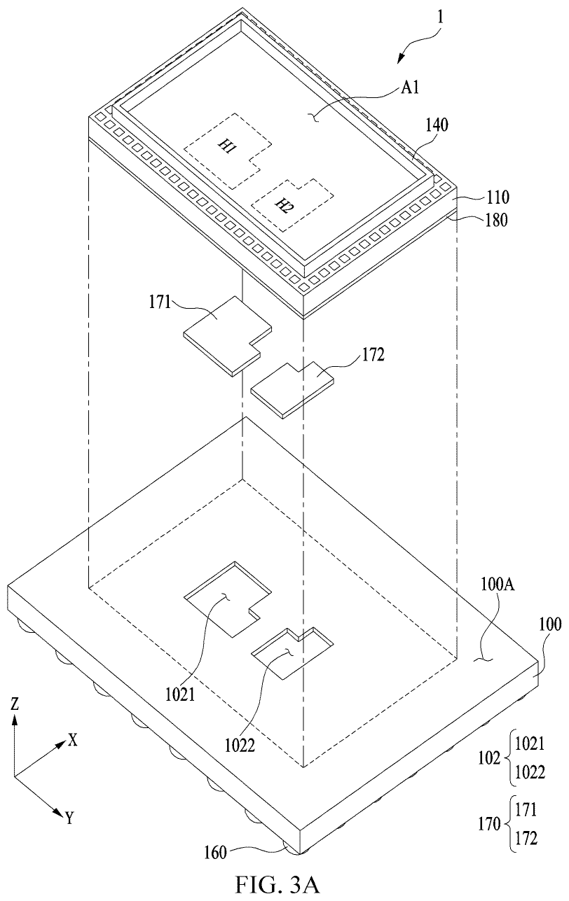

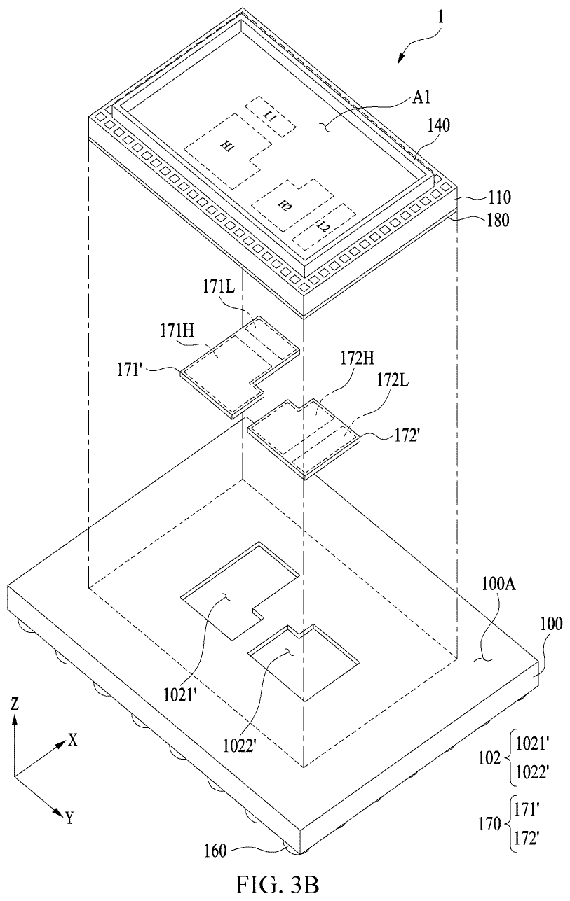

FIG. 1A is a plan view of an example of an image sensor chip according to an embodiment. FIG. 1B is a simulation graph depicting the temperature deviation between portions of the exemplary image sensor chip. FIG. 2 is a cross-sectional view of a semiconductor package according to an embodiment. FIG. 3A is an exploded perspective view of the semiconductor package according to an embodiment. FIG. 3B is an exploded perspective view of the semiconductor package according to an embodiment.

Referring to FIG. 1, an image sensor chip 110 may include an image sensing area A1 in which a plurality of unit pixels are arranged in an array form, and a non-sensing area A2. When a first surface of the image sensor chip 110 is viewed, the non-sensing area A2 may be positioned on the edges of the image sensor chip 110 to surround the image sensing area A1. A plurality of chip pads 111 positioned in the non-sensing area A2 may be arranged on the first surface of the image sensor chip 110. The plurality of chip pads 111 may be formed of a conductive metal (e.g., aluminum, copper, etc.). A dam area A3 may be formed on the first surface of the image sensor chip 110 to surround the image sensing area A1 and to install a bonding dam therein, which will be described later.

Each of the plurality of unit pixels positioned in the image sensing area A1 may detect light using a photodiode (PD) and generate an image signal by converting the detected light into an electrical signal. For example, the plurality of unit pixels may include complementary metal-oxide-semiconductor (CMOS) image sensors. However, this is merely an example, and the plurality of unit pixels may include charge-coupled device (CCD) image sensors, and are not limited to the illustrated example.

The image sensor chip 110 may have heat generation that varies depending on its portion. For example, in the image sensor chip 110, a portion where a logic circuit is positioned may generate more heat than the other portion. In the image sensor chip 110, one or more high-temperature areas H1 and H2 and one or more low-temperature areas L1 and L2 may be defined. For example, the high-temperature areas H1 and H2 may be areas that generate more heat than the remaining area of the image sensor chip 110. For example, the low-temperature areas L1 and L2 may be areas that generate less heat than the remaining area of the image sensor chip 110. The high-temperature areas H1 and H2 may be defined, for example, as areas belonging to the top N % (where N is a predetermined positive number) of the total temperature range that appears when the image sensor chip 110 is used. The low-temperature areas L1 and L2 may be defined, for example, as areas belonging to the bottom M % (where M is a predetermined positive number) of the overall temperature range that appears when the image sensor chip 110 is used. In another example, the high-temperature areas H1 and H2 may be defined as areas each having a temperature at least A degrees (where A is a predetermined positive number) higher than the average temperature of the image sensor chip 110. The low-temperature areas L1 and L2 may be defined, for example, as areas each having a temperature at least B degrees (where B is a predetermined positive number) lower than the average temperature of the image sensor chip 110.

When a plurality of high-temperature areas H1 and H2 are defined in the image sensor chip 110, it may be understood that the high-temperature areas H1 and H2 may be different in heat generation but may generate more heat than the remaining area of the image sensor chip 110. Similarly, when a plurality of low-temperature areas L1 and L2 are defined in the image sensor chip 110, it may be understood that the low-temperature areas L1 and L2 may be different in heat generation but may generate less heat than the remaining area of the image sensor chip 110. It should be understood that the shapes, positions, and numbers of high-temperature areas H1 and H2 and low-temperature areas L1 and L2 shown in the drawings are merely examples for ease of description and are not limited to the drawings and the description of embodiments. Hereinafter, for ease of description, two high-temperature areas H1 and H2 and two low-temperature areas L1 and L2 are defined for the image sensor chip 110, and the following embodiments are described based on the defined areas unless otherwise stated.

FIG. 1B is a simulation graph to confirm the temperature deviation between portions of a predetermined exemplary image sensor chip. Referring to FIG. 1B, it may be confirmed that the temperature varies from portion to portion of an image sensor chip, while the image sensor chip is used. The simulation results in FIG. 1B should be understood as only an example to describe that the temperature varies from portion to portion while the image sensor chip is used, and the temperature distribution and temperature values shown in the simulation results are merely examples observed at predetermined points in time for a predetermined image sensor chip, and embodiments are not limited thereto.

As shown in FIG. 1B, the image sensor chip may exhibit a temperature that varies from portion to portion during the use, based on a plane. The simulation results in FIG. 1B represent the temperature of each portion of the image sensor chip in the form of an index, where it may be confirmed that the highest-temperature portion of the image sensor chip shows a temperature index of about “98”, and the lowest-temperature portion shows a temperature index of about “95”. For example, while the image sensor chip is used, it may be confirmed that an area generating more heat and an area generating less heat are distinguished according to the design of the image sensor chip.

Referring to the simulation results of FIG. 1B, one or more high-temperature areas H1 and H2 of which the temperature is higher than that of the other areas and one or more low-temperature areas L1 and L2 of which the temperature is lower than that of the other areas may be defined in the image sensor chip. The defined high-temperature areas H1 and H2 may include the area with the highest temperature and its surrounding area in the image sensor chip, respectively. For example, the high-temperature areas H1 and H2 may be defined by areas having temperature indices in the range of “97” to “99” in the image sensor chip as boundaries. The defined low-temperature areas L1 and L2 may be defined by the area with the lowest temperature and its surrounding area in the image sensor chip as boundaries, respectively. For example, the low-temperature areas L1 and L2 may be defined by areas having temperature indices in the range of “95” to “96” as boundaries. It should be noted that high-temperature areas and low-temperature areas may be set differently depending on the type and specifications of an image sensor chip used in a semiconductor package and may be set by areas having relatively high temperatures and areas having relatively low temperatures as boundaries according to the overall heat generation simulation results of the image sensor chip.

Hereinafter, in describing a semiconductor package, embodiments will be described assuming that predetermined numbers of high-temperature areas and low-temperature areas of an image sensor chip are defined at predetermined positions.

Referring to FIG. 2, a semiconductor package 1 may be a semiconductor package 1 for an image sensor. The semiconductor package 1 may include a semiconductor substrate 100, an image sensor chip 110 arranged on the semiconductor substrate 100, a conductive wire 150 electrically connecting the image sensor chip 110 and the semiconductor substrate 100, a cover glass 120 arranged to cover an upper portion of the image sensor chip 110, a bonding dam 140 positioned between (e.g., connecting) the image sensor chip 110 and the cover glass 120, a molding member 130 surrounding the image sensor chip 110, a plurality of connecting terminals 160 arranged on a lower portion of the semiconductor substrate 100, and one or more heat dissipation members 170 to perform a heat dissipation function between the image sensor chip 110 and the semiconductor substrate 100. For example, the semiconductor package 1 may be a ball grid array (BGA) in which the connecting terminals 160 are formed as solder balls.

The semiconductor substrate 100 (or substrate) may support the image sensor chip 110. The semiconductor substrate 100 may include a first substrate surface 100A on which the image sensor chip 110 is arranged, and a second substrate surface 100B opposite to the first substrate surface 100A. A redistribution layer (RDL) 101 may be formed on the semiconductor substrate 100. The redistribution layer 101 may form an electrical path extending from the first substrate surface 100A to the second substrate surface 100B of the semiconductor substrate 100. For example, a plurality of first connection pads 1011 to which conductive wires 150 are connected may be arranged on the first substrate surface 100A of the semiconductor substrate 100, and a plurality of second connection pads 1012 to which the connecting terminals 160 are connected may be arranged on the second substrate surface 100B of the semiconductor substrate 100. The redistribution layer 101 may electrically connect the first connection pads 1011 and the second connection pads 1012. For example, the redistribution layer 101 may include a plurality of redistribution line patterns, a plurality of redistribution vias, and a redistribution insulating layer. The redistribution insulating layer may be formed from, for example, photo imageable dielectric (PID) or photosensitive polyimide (PSPI). The redistribution line patterns and the redistribution vias may include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or an alloy thereof, but are not limited thereto. As an example, the redistribution line patterns and the redistribution vias may be formed by stacking the metal or alloy on a seed layer including titanium, titanium nitride, or titanium tungsten.

The plurality of first connection pads 1011 may be arranged on the first substrate surface 100A of the semiconductor substrate 100. The plurality of first connection pads 1011 may be arranged on the edges of the semiconductor substrate 100 to be positioned outside the perimeter of the image sensor chip 110. Although only two first connection pads 1011 are shown in the drawing, this is for ease of description through a cross-sectional view. It should be noted that the plurality of first connection pads 1011 respectively connected to a plurality of chip pads 111 formed on the image sensor chip 110 through the conductive wires 150 are arranged on the first substrate surface 100A of the semiconductor substrate 100.

The image sensor chip 110 may be mounted on the first substrate surface 100A of the semiconductor substrate 100. The image sensor chip 110 may include a first surface 110A and a second surface 110B opposite to the first surface 110A. The image sensor chip 110 may be arranged so that the second surface 110B may face the first substrate surface 100A of the semiconductor substrate 100. The plurality of chip pads 111 positioned on the edges may be arranged on the first surface 110A of the image sensor chip 110. The chip pads 111 may be electrically connected to the redistribution layer 101 of the semiconductor substrate 100 through the conductive wires 150. The chip pads 111 may include a conductive layer including a metal, a metal nitride, a conductive carbon, or a combination thereof. The chip pads 111 may include, for example, copper (Cu), cobalt (Co), aluminum (Al), tin (Sn), nickel (Ni), gold (Au), silver (Ag), tungsten (W), tungsten nitride (WN), titanium (Ti), titanium nitride (TiN), tantalum (Ta), tantalum nitride (TaN), ruthenium (Ru), platinum (Pt), or a combination thereof. The chip pads 111 may be electrically connected to semiconductor devices formed on the image sensor chip 110.

A bonding member 180 may be arranged between the semiconductor substrate 100 and the image sensor chip 110. The bonding member 180 may be formed between the first substrate surface 100A of the semiconductor substrate 100 and the second surface 110B of the image sensor chip 110 and may bond the image sensor chip 110 to the semiconductor substrate 100. The bonding member 180 may be formed by a bonding material applied to the first substrate surface 100A of the semiconductor substrate 100 during the process of manufacturing the semiconductor package 1.

The conductive wire 150 may electrically connect the image sensor chip 110 to the redistribution layer 101 of the semiconductor substrate 100. Both ends of the conductive wire 150 may be connected to a chip pad 111 of the image sensor chip 110 and a first connection pad 1011 of the semiconductor substrate 100, respectively. The semiconductor package 1 may include a plurality of conductive wires 150, and the conductive wires 150 may individually connect the chip pads 111 formed on the image sensor chip 110 and the plurality of first connection pads 1011 formed on the semiconductor substrate 100. The conductive wires 150 may be connected to the chip pads 111 and the first connection pads 1011, for example, through soldering. The image sensor chip 110 may be electrically connected to circuits arranged on the semiconductor substrate 100 through the conductive wires 150.

The cover glass 120 may be arranged above the image sensor chip 110. The cover glass 120 may cover the first surface 110A of the image sensor chip 110 while facing the first surface 110A of the image sensor chip 110. The cover glass 120 may be formed of a light-transmitting material so that light may be incident to the first substrate surface 100A of the image sensor chip 110 through the cover glass 120. For example, the cover glass 120 may protect the image sensor chip 110 while also serving as an optical path that allows light to be input into the image sensor chip 110. The cover glass 120 may be formed to have widths corresponding to, for example, the X-axis and Y-axis widths of the image sensor chip 110, but is not limited thereto, and may be formed to have a width greater than the X-axis and/or Y-axis width of the image sensor chip 110.

The bonding dam 140 may be formed between the image sensor chip 110 and the cover glass 120, and may bond the image sensor chip 110 and the cover glass 120. The bonding dam 140 may be arranged on the first surface 110A of the image sensor chip 110 and formed to surround the image sensing area A1 of the image sensor chip 110 in a closed loop shape. For example, the bonding dam 140 may be arranged along the bonding area A3 formed on the outside of the image sensing area A1, as shown in FIG. 1. Since the cover glass 120 faces the first surface 110A of the image sensor chip 110 by the bonding dam 140, an empty space G having a thickness corresponding to the thickness of the bonding dam 140 may be formed between the image sensor chip 110 and the cover glass 120. The bonding dam 140 may prevent a molding material forming the molding member 130 from flowing into the empty space G formed between the image sensor chip 110 and the cover glass 120, during the process of forming the molding member 130 in the semiconductor package 1.

The molding member 130 may be arranged on the upper portion of the semiconductor substrate 100 and may surround the image sensor chip 110 to protect the image sensor chip 110. The molding member 130 may be formed, for example, of an epoxy mold compound (EMC). The EMC may include, for example, a resin-based resin, a filler, and a curing agent. The molding member 130 may be formed to surround the image sensor chip 110 between the upper portion of the semiconductor substrate 100 and the cover glass 120. The molding member 130 may be formed to surround the lower portion of the cover glass 120 and arranged to fill the empty space between the cover glass 120 and the image sensor chip 110 along the perimeter of the bonding dam 140. For example, the non-sensing area A2 of the image sensor chip 110 may be covered by the molding member 130. The molding member 130 may cover the edges of the first substrate surface 100A of the semiconductor substrate 100. Since the conductive wire 150 is surrounded by the molding member 130, the connection structure of the image sensor chip 110 and the semiconductor substrate 100 through the conductive wire 150 may be maintained more firmly.

The connecting terminals 160 may be connected to the second substrate surface 100B of the semiconductor substrate 100. The connecting terminals 160 may be, for example, soldered to the second connection pads 1012 exposed on the second substrate surface 100B of the semiconductor substrate 100 and electrically connected to the redistribution layer 101. The semiconductor package 1 may be electrically connected to another semiconductor package 1, a motherboard, or the like through the connecting terminals 160. The plurality of connecting terminals 160 may be arranged in an array on the second substrate surface 100B of the semiconductor substrate 100. The connecting terminals 160 may be arranged in a fan-out structure on the semiconductor substrate 100, as shown in FIG. 2. The connecting terminals 160 may be omitted from the second substrate surface 100B of the semiconductor substrate 100 corresponding to the Z-directional lower portion of the image sensor chip 110, but are not limited thereto. The connecting terminals 160 may be, for example, solder balls, but are not limited thereto.

The heat dissipation member 170 may be arranged on the semiconductor substrate 100. The heat dissipation member 170 may be embedded in the first substrate surface 100A of the semiconductor substrate 100. For example, a recess 102 may be defined on the first substrate surface 100A of the semiconductor substrate 100, and the heat dissipation member 170 may be seated in the recess 102. Recess 102 may extend, at least partially, within semiconductor substrate 100 from the first substrate surface 100A. In a state in which the heat dissipation member 170 is arranged in the recess 102, the surface of the heat dissipation member 170 facing the image sensor chip 110 may be co-planar with the first substrate surface 100A of the semiconductor substrate 100. Being co-planar, the top surface of a heat dissipation member 170 may be approximately at the same level as the first substrate surface 100A of the semiconductor substrate 100. The heat dissipation member 170 may be in direct contact with the lower portion of the image sensor chip 110. A plurality of heat dissipation members 170 may be arranged on the semiconductor substrate 100. In this case, a plurality of recesses 102 may be formed on the first substrate surface 100A of the semiconductor substrate 100, and the heat dissipation members 170 may be arranged in the recesses 102, respectively. For example, a first recess 1021 and a second recess 1022 may be formed on the first substrate surface 100A of the semiconductor substrate 100, and a first heat dissipation member 171 and a second heat dissipation member 172 may be arranged in the first recess 1021 and the second recess 1022, respectively.

The heat dissipation member 170 may form a heat conduction path between the image sensor chip 110 and the semiconductor substrate 100, thereby improving the effect of heat dissipation from the image sensor chip 110 to the semiconductor substrate 100. The heat dissipation member 170 may be arranged in the recess 102 formed in the first substrate surface 100A of the semiconductor substrate 100.

The heat dissipation member 170 may be formed of a material having high thermal conductivity. For example, the heat dissipation member 170 may be formed of a material having a higher thermal conductivity than a non-metallic portion (e.g., polyimide (PI)) of the semiconductor substrate 100. The heat dissipation member 170 may be formed of a metal material having high thermal conductivity, for example, any one material of copper (Cu), aluminum (Al), silver (Au), zinc (Zn), tungsten, magnesium (Mg), molybdenum, an aluminum alloy, or combinations thereof. In another example, the heat dissipation member 170 may be formed of a graphite material having high thermal conductivity. In still another example, the heat dissipation member 170 may be formed of a non-conductive material. For example, the heat dissipation member 170 may be formed of a synthetic resin including a thermally conductive filler. However, the materials of the heat dissipation member 170 described above are merely examples, and the material of the heat dissipation member 170 is not limited to the materials mentioned above.

The heat dissipation member 170 may be electrically insulated from the redistribution layer 101 of the semiconductor substrate 100. Therefore, when the image sensor chip 110 comes into contact with the heat dissipation member 170, an electrical path between the semiconductor substrate 100 and the image sensor chip 110 through the heat dissipation member 170 may not be formed. Therefore, when the heat dissipation member 170 is formed of a conductive material, a short circuit in the semiconductor package 1 caused by the heat dissipation member 170 may be prevented.

The heat dissipation member 170 may be positioned at a position overlapping with the image sensing area A1 of the image sensor chip 110, when the second surface 110B of the image sensor chip 110 is viewed (e.g., when viewed in the −Z direction of FIG. 2). The heat dissipation member 170 may be arranged to overlap with a portion of the image sensor chip 110 that generates more heat. For example, the heat dissipation member 170 may improve the effect of heat dissipation from a portion of the image sensor chip 110 that generates more heat to the semiconductor substrate 100.

Referring to FIG. 3A, an example of a structure in which heat dissipation members 170 are arranged on the semiconductor package 1 will be described. It should be noted that some components such as the cover glass 120, the conductive wire 150, and the molding member 130 are omitted from FIG. 3A for ease of description.

In the image sensor chip 110, a plurality of high-temperature areas generating more heat than the surrounding area may be defined. For example, a first high-temperature area H1 and a second high-temperature area H2 that are spaced apart from each other may be defined in the image sensor chip 110. For example, the first high-temperature area H1 and the second high-temperature area H2 may be areas where a logic circuit of the image sensor chip 110 or a mobile industry processor interface (MIPI) is arranged. Each of the high-temperature areas may be positioned within an image sensing area A1 of the image sensor chip 110 surrounded by a bonding dam 140.

The semiconductor substrate 100 may support the image sensor chip 110 through the first substrate surface 100A. Connecting terminals 160 may be arranged on the lower portion of the semiconductor substrate 100. Recesses 102 may be defined on the first substrate surface 100A of the semiconductor substrate 100. For example, a first recess 1021 and a second recess 1022 may be formed on the first substrate surface 100A. The respective recesses 102 may be formed in portions of the semiconductor substrate 100 corresponding to the first high-temperature area H1 and the second high-temperature area H2 of the image sensor chip 110. The heat dissipation members 170 may be arranged in the recesses 102, respectively. For example, the first heat dissipation member 171 may be arranged in the first recess 1021, and the second heat dissipation member 172 may be arranged in the second recess 1022. The first heat dissipation member 171 and the second heat dissipation member 172 may be formed to have shapes and thicknesses corresponding to those of the first recess 1021 and the second recess 1022, respectively, so that when embedded in the first substrate surface 100A, the surfaces thereof may be co-planar with the other portion of the first substrate surface 100A. Each of the heat dissipation members 170 may be electrically insulated from the redistribution layer 101 of the semiconductor substrate 100. The first heat dissipation member 171 and the second heat dissipation member 172 may be formed to have the same thickness.

As shown in FIG. 2, based on a state in which the image sensor chip 110 is attached to the first substrate surface 100A of the semiconductor substrate 100, the first heat dissipation member 171 may overlap with the first high-temperature area H1 of the image sensor chip 110, and the second heat dissipation member 172 may overlap with the second high-temperature area H2 of the image sensor chip 110. The heat dissipation members 170 may function to receive heat generated from the respective high-temperature areas of the image sensor chip 110 and dissipate the heat to the surrounding area of the semiconductor substrate 100. For example, the heat dissipation members 170 may disperse heat from an area of the semiconductor substrate 100 that receives heat from a high-temperature area of the image sensor chip 110 to a surrounding area that receives a relatively small amount of heat therefrom, thereby reducing the temperature deviation between portions of the semiconductor substrate 100.

Referring to FIG. 3B, a plurality of high-temperature areas H1 and H2 and a plurality of low-temperature areas L1 and L2 may be defined in the image sensor chip 110. For example, a first high-temperature area H1, a second high-temperature area H2, a first low-temperature area L1, and a second low-temperature area L2 may be defined in the image sensor chip 110. The low-temperature areas L1 and L2 may generate less heat than the remaining area of the image sensor chip 110. Each of the high-temperature areas H1 and H2 and the low-temperature areas L1 and L2 may be positioned within an image sensing area A1 of the image sensor chip 110 surrounded by a bonding dam 140.

A first recess 1021′ and a second recess 1022′ may be defined on the first substrate surface 100A of the semiconductor substrate 100. A first heat dissipation member 171′ may be arranged in the first recess 1021′, and a second heat dissipation member 172′ may be arranged in the second recess 1022′. As shown in FIG. 2, based on a state in which the image sensor chip 110 is attached to the first substrate surface 100A of the semiconductor substrate 100, at least one heat dissipation member 170 may overlap with at least one high-temperature area H1 and H2 and at least one low-temperature area L1 and L2. For example, the first heat dissipation member 171′ may overlap with the first high-temperature area H1 and the first low-temperature area L1. The second heat dissipation member 172′ may overlap with the second high-temperature area H2 and the second low-temperature area L2. The first heat dissipation member 171′ may include a first-first heat dissipation portion 171H overlapping with the first high-temperature area H1 and a first-second heat dissipation portion 171L overlapping with the first low-temperature area L1. The second heat dissipation member 172′ may include a second-first heat dissipation portion 172H overlapping with the second high-temperature area H2 and a second-second heat dissipation portion 172L overlapping with the second low-temperature area L2. Unlike the example shown, at least one of the first heat dissipation member 171′ and the second heat dissipation member 172′ may overlap only with the high-temperature areas H1 and H2. Although not shown, each of the heat dissipation members 171′ and 172′ may be formed to have a thickness that varies from portion to portion. For example, the heat dissipation member 170 may be formed so that the heat dissipation portions 171H and 172H overlapping with the high-temperature areas H1 and H2 may have a greater thickness than the heat dissipation portions 171L and 172L overlapping with the low-temperature areas L1 and L2.

When the first heat dissipation member 171′ is arranged to overlap with the first high-temperature portion H1 and the first low-temperature portion L1 of the image sensor chip 110, the first heat dissipation member 171′ may receive heat from the first high-temperature portion H1 of the image sensor chip 110 through the first-first heat dissipation portion 171H and transmit the heat to the first-second heat dissipation portion 171L. Since the portion of the semiconductor substrate 100 where the first-second heat dissipation portion 171L is positioned corresponds to the first low-temperature area L1 where the temperature is low in the image sensor chip 110, the first heat dissipation member 171′ may disperse heat from the first-first heat dissipation portion 171H that receives a relatively large amount of heat to the first-second heat dissipation portion 171L that receives a relatively small amount of heat. Similarly, the second heat dissipation member 172′ may receive heat from the second high temperature part H2 of the image sensor chip 110 through the second-first heat dissipation portion 172H and transmit the heat to the second-second heat dissipation portion 172L. For example, since one heat dissipation member 170 may simultaneously overlap with the high-temperature areas H1 and H2 and the low-temperature areas L1 and L2 of the image sensor chip 110 to disperse heat on the semiconductor substrate 100, the temperature deviation between portions of the semiconductor substrate 100 may be effectively reduced.

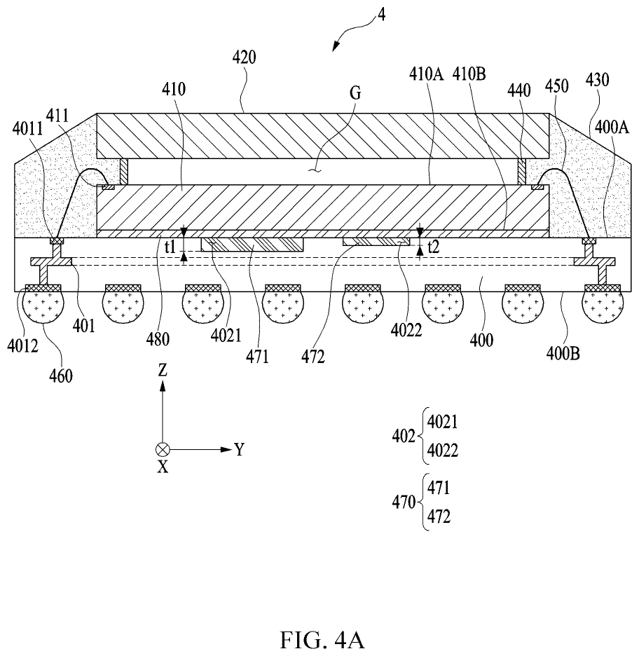

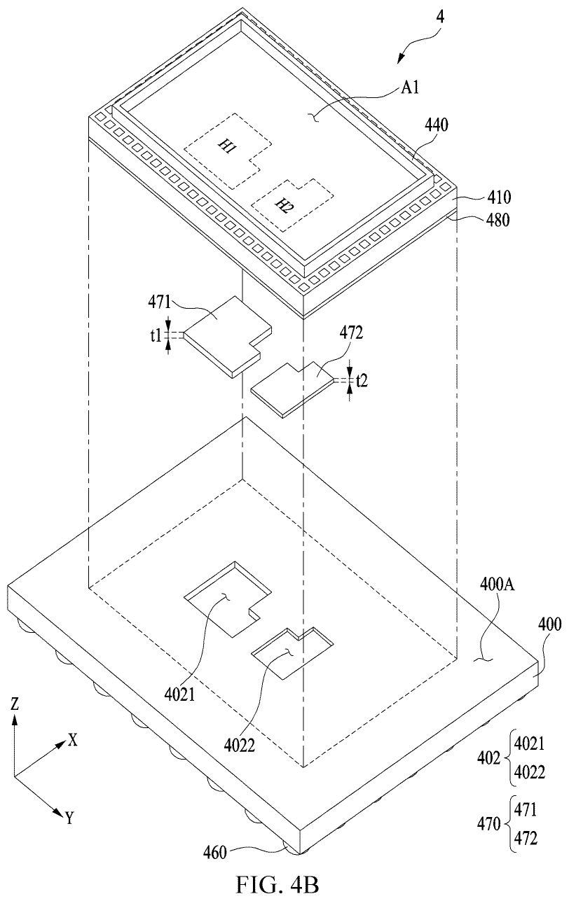

FIG. 4A is a cross-sectional view of a semiconductor package according to an embodiment. FIG. 4B is an exploded perspective view of the semiconductor package according to an embodiment.

Referring to FIGS. 4A and 4B, a semiconductor package 4 may include a semiconductor substrate 400 including a redistribution layer 401, an image sensor chip 410 arranged on a first substrate surface 400A of the semiconductor substrate 400, a conductive wire 450 electrically connecting the image sensor chip 410 and the redistribution layer 401 of the semiconductor substrate 400, a cover glass 420 arranged to cover an upper portion of the image sensor chip 410, a bonding dam 440 forming a gap between the image sensor chip 410 and the cover glass 420 and connecting the image sensor chip 410 and the cover glass 420, a molding member 430 surrounding the image sensor chip 410, a plurality of connecting terminals 460 arranged on a second substrate surface 400B of the semiconductor substrate 400, and one or more heat dissipation members 470.

The semiconductor substrate 400 may include the first substrate surface 400A and the second substrate surface 400B opposite to the first substrate surface 400A. First connection pads 4011 to which conductive wires 450 are connected may be exposed on the first substrate surface 400A, and second connection pads 4012 may be exposed on the second substrate surface 400B. The plurality of connecting terminals 460 may be arranged on the second substrate surface 400B to be electrically connected to the redistribution layer 401 through the second connection pads 4012.

The image sensor chip 410 may include a first surface 410A and a second surface 410B opposite to the first surface 410A. The image sensor chip 410 may be arranged so that the second surface 410B may face the first substrate surface 400A of the semiconductor substrate 400. A bonding member 480 may be arranged between the semiconductor substrate 400 and the image sensor chip 410. A chip pad 411 positioned outside the edges of the bonding dam 440 and connected with the conductive wire 450 may be arranged on the first surface 410A of the image sensor chip 410.

A plurality of high-temperature areas H1 and H2 may be defined in the image sensor chip 410. For example, a first high-temperature area H1 and a second high-temperature area H2 may be defined in the image sensor chip 410. The first high-temperature area H1 and the second high-temperature area H2 may be arranged to overlap within the image sensing area A1 of the image sensor chip 410. The first high-temperature area H1 may generate more heat than the second high-temperature area H2.

One or more recesses 402 may be defined on the first substrate surface 400A of the semiconductor substrate 400. For example, a first recess 4021 overlapping the first high-temperature area H1 of the image sensor chip 410 and a second recess 4022 overlapping the second high-temperature area H2 of the image sensor chip 410 may be formed on the first substrate surface 400A. A first heat dissipation member 471 may be arranged in the first recess 4021, and a second heat dissipation member 472 may be arranged in the second recess 4022. The first heat dissipation member 471 and the second heat dissipation member 472 may be formed to have shapes and thicknesses corresponding to those of the first recess 4021 and the second recess 4022, respectively, so that when embedded in the first substrate surface 400A, the surfaces thereof may be co-planar with the other portion of the first substrate surface 400A. Each of the heat dissipation members 470 may be electrically insulated from the redistribution layer 401 of the semiconductor substrate 400.

The plurality of heat dissipation members 470 arranged on the semiconductor substrate 400 may be formed to have different thicknesses. For example, the first heat dissipation member 471 may be formed to have a first thickness t1, and the second heat dissipation member 472 may be formed to have a second thickness t2 smaller than the first thickness t1. As shown in FIG. 4A, based on a state in which the image sensor chip 410 is attached to the second substrate surface 400B of the semiconductor substrate 400, the first heat dissipation member 471 may overlap with the first high-temperature area H1 of the image sensor chip 410, and the second heat dissipation member 472 may overlap with the second high-temperature area H2 of the image sensor chip 410. Since the heat dissipation performance improves as the thickness of a heat dissipation member 470 increases, the first heat dissipation member 471 may have higher heat dissipation performance than the second heat dissipation member 472. When the first high-temperature area H1 generates more heat than the second high-temperature area H2, forming the first heat dissipation member 471 to be thicker than the second heat dissipation member 472 may allow more effective dissipation of the heat generated in the first high-temperature area H1. In addition, forming the second heat dissipation member 472 to be thinner than the first heat dissipation member 471 may minimize the space to form the recesses 402 required when installing the heat dissipation members 470 on the semiconductor substrate 400.

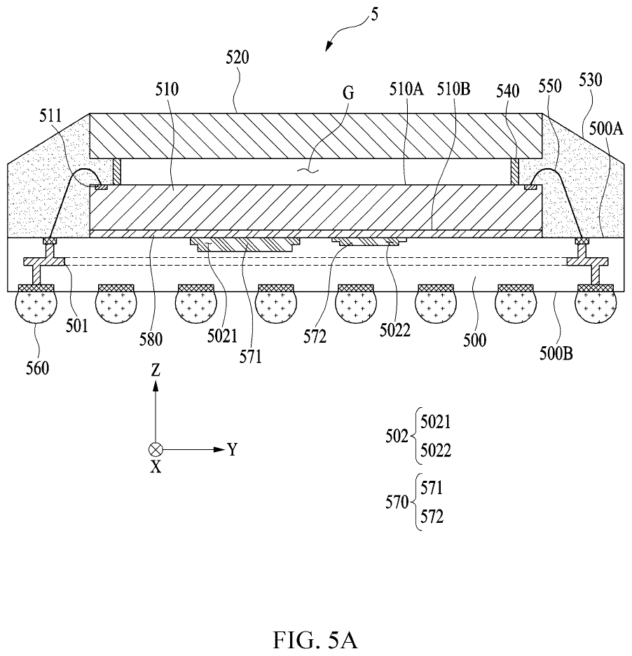

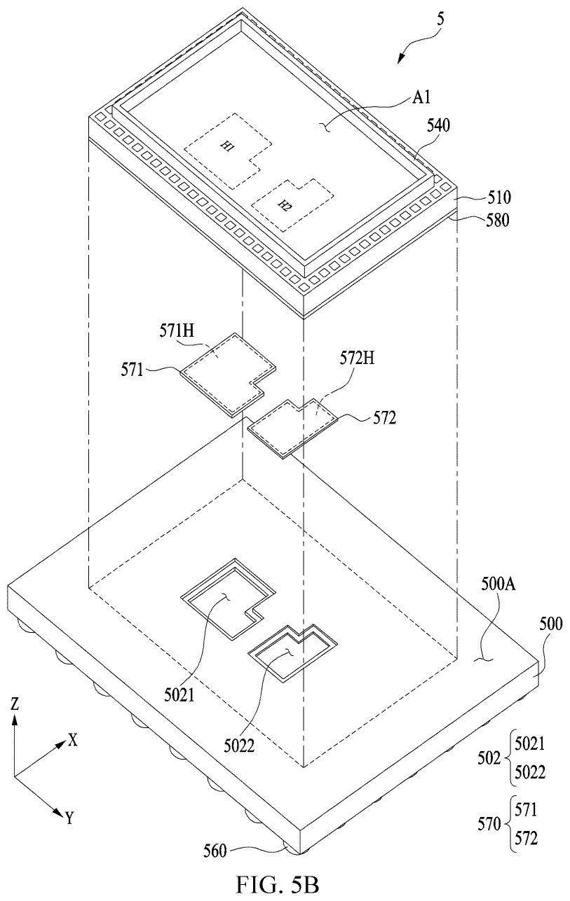

FIG. 5A is a cross-sectional view of a semiconductor package according to an embodiment. FIG. 5B is an exploded perspective view of the semiconductor package according to an embodiment.

Referring to FIGS. 5A and 5B, a semiconductor package 5 may include a semiconductor substrate 500 including a redistribution layer 501, an image sensor chip 510 arranged on a first substrate surface 500A of the semiconductor substrate 500, a conductive wire 550 electrically connecting the image sensor chip 510 and the redistribution layer 501 of the semiconductor substrate 500, a cover glass 520 arranged to cover an upper portion of the image sensor chip 510, a bonding dam 540 forming a gap G between the image sensor chip 510 and the cover glass 520 and connecting the image sensor chip 510 and the cover glass 520, a molding member 530 surrounding the image sensor chip 510, a plurality of connecting terminals 560 arranged on a second substrate surface 500B of the semiconductor substrate 500, and one or more heat dissipation members 570.

The semiconductor substrate 500 may include the first substrate surface 500A and the second substrate surface 500B opposite to the first substrate surface 500A. The plurality of connecting terminals 560 may be arranged on the second substrate surface 500B to be electrically connected to the redistribution layer 501 through the second connection pads 5012.

The image sensor chip 510 may include a first surface 510A and a second surface 510B opposite to the first surface 510A. The image sensor chip 510 may be arranged so that the second surface 510B may face the first substrate surface 500A of the semiconductor substrate 500. A bonding member 580 may be arranged between the semiconductor substrate 500 and the image sensor chip 510. A chip pad 511 positioned outside the edges of the bonding dam 540 and connected with the conductive wire 550 may be arranged on the first surface 510A of the image sensor chip 510.

A plurality of high-temperature areas H1 and H2 may be defined in the image sensor chip 510. For example, a first high-temperature area H1 and a second high-temperature area H2 may be defined in the image sensor chip 510. The first high-temperature area H1 and the second high-temperature area H2 may be arranged to overlap within the image sensing area A1 of the image sensor chip 510. The first high-temperature area H1 may generate more heat than the second high-temperature area H2.

One or more recesses 502 may be defined on the first substrate surface 500A of the semiconductor substrate 500. For example, a first recess 5021 overlapping the first high-temperature area H1 of the image sensor chip 510 and a second recess 5022 overlapping the second high-temperature area H2 of the image sensor chip 510 may be formed on the first substrate surface 500A. A first heat dissipation member 571 may be arranged in the first recess 5021, and a second heat dissipation member 572 may be arranged in the second recess 5022. The first heat dissipation member 571 and the second heat dissipation member 572 may be formed to have shapes and thicknesses corresponding to those of the first recess 5021 and the second recess 5022, respectively, so that when embedded in the first substrate surface 500A, the surfaces thereof may be co-planar with the other portion of the first substrate surface 500A. Each of the heat dissipation members 570 may be electrically insulated from the redistribution layer 501 of the semiconductor substrate 500.

Each of the heat dissipation members 570 may be formed to have an area larger than a corresponding high-temperature area of the image sensor chip 510. Each of the heat dissipation members 570 may include a first heat dissipation portion 571H or 572H corresponding to a high-temperature area, and a second heat dissipation portion surrounding the first heat dissipation portion and having a smaller thickness than the first heat dissipation portion. For example, the first heat dissipation member 571 may include a first-first heat dissipation portion 571H overlapping with the first high-temperature area H1 and a second-first heat dissipation portion surrounding the first-first heat dissipation portion 571H. The first heat dissipation member 571 may be formed so that the first-first heat dissipation portion 571H may have a greater thickness than the second-first heat dissipation portion. The second heat dissipation member 572 may be formed so that a first-second heat dissipation portion 572H may have a greater thickness than a second-second heat dissipation portion.

Since the heat dissipation performance improves as the thickness of a heat dissipation member 570 increases, forming each of the heat dissipation members 571 and 572 so that the first heat dissipation portion 571H or 572H overlapping a high-temperature area is thicker than the second heat dissipation portion non-overlapping with a high-temperature area may improve heat dissipation performance on the semiconductor substrate 500. At the same time, forming the second heat dissipation portion to be thinner than the first heat dissipation portion 571H or 572H may reduce the space to form the recesses 502 required when installing the heat dissipation members 570 on the semiconductor substrate 500.

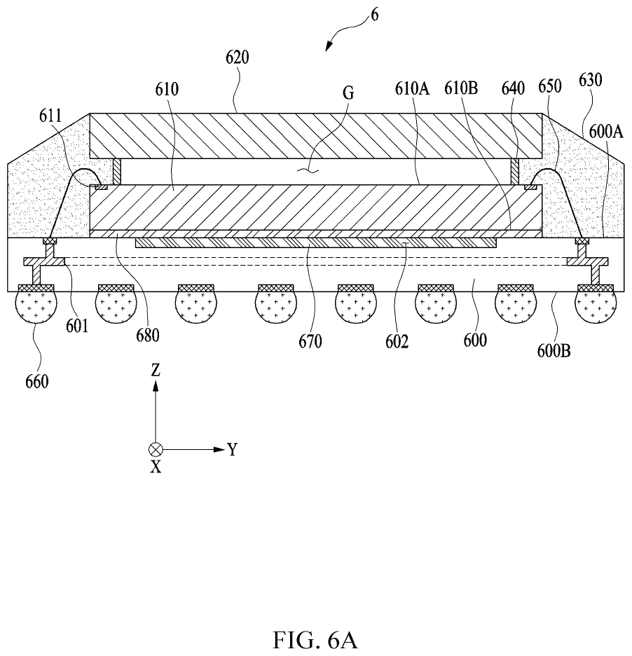

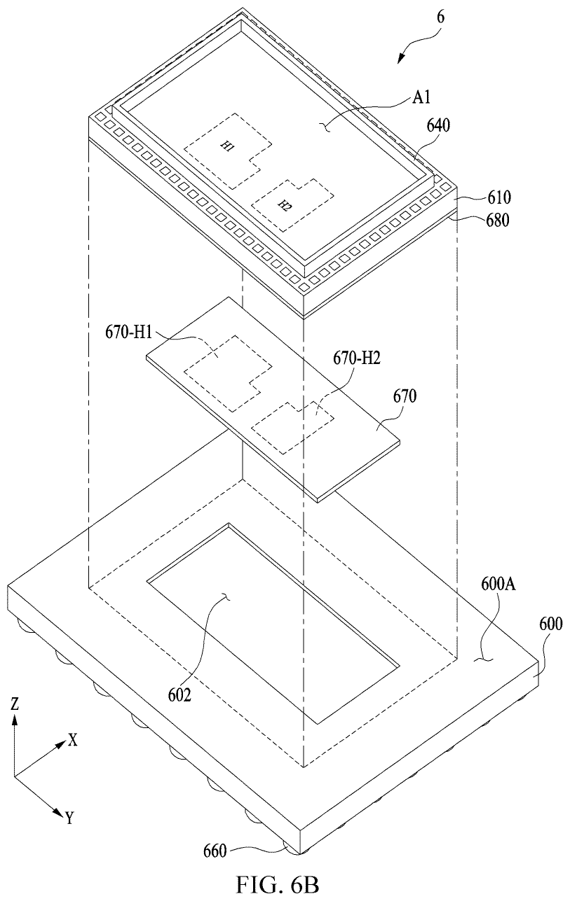

FIG. 6A is a cross-sectional view of a semiconductor package according to an embodiment. FIG. 6B is an exploded perspective view of the semiconductor package according to an embodiment.

Referring to FIGS. 6A and 6B, a semiconductor package 6 may include a semiconductor substrate 600 including a redistribution layer 601, an image sensor chip 610 arranged on a first substrate surface 600A of the semiconductor substrate 600, a conductive wire 650 electrically connecting the image sensor chip 610 and the redistribution layer 601 of the semiconductor substrate 600, a cover glass 620 arranged to cover an upper portion of the image sensor chip 610, a bonding dam 640 forming a gap G between the image sensor chip 610 and the cover glass 620 and connecting the image sensor chip 610 and the cover glass 620, a molding member 630 surrounding the image sensor chip 610, a plurality of connecting terminals 660 arranged on a second substrate surface 600B of the semiconductor substrate 600, and a heat dissipation member 670.

The semiconductor substrate 600 may include the first substrate surface 600A and the second substrate surface 600B opposite to the first substrate surface 600A. The plurality of connecting terminals 660 may be arranged on the second substrate surface 600B to be electrically connected to the redistribution layer 601 through the second connection pads 6012.

The image sensor chip 610 may include a first surface 610A and a second surface 610B opposite to the first surface 610A. The image sensor chip 610 may be arranged so that the second surface 610B may face the first substrate surface 600A of the semiconductor substrate 600. A bonding member 680 may be arranged between the semiconductor substrate 600 and the image sensor chip 610. A chip pad 611 positioned outside the edges of the bonding dam 640 and connected with the conductive wire 650 may be arranged on the first surface 610A of the image sensor chip 610.

A plurality of high-temperature areas H1 and H2 may be defined in the image sensor chip 610. For example, a first high-temperature area H1 and a second high-temperature area H2 may be defined in the image sensor chip 610. The first high-temperature area H1 and the second high-temperature area H2 may be arranged to overlap within the image sensing area A1 of the image sensor chip 610. The first high-temperature area H1 may generate more heat than the second high-temperature area H2.

A recess 602 may be defined on the first substrate surface 600A of the semiconductor substrate 600. The heat dissipation member 670 may be seated in the recess 602. The recess 602 and the heat dissipation member 670 may be formed with an area overlapping with the entire image sensing area A1 of the image sensor chip 610. For example, in a state in which the first surface 610A of the image sensor chip 610 is viewed, the heat dissipation member 670 may overlap with the entire image sensing area A1 of the image sensor chip 610. When the heat dissipation member 670 is embedded in the first substrate surface 600A, the surface thereof may be co-planar with the surrounding area of the first substrate surface 600A. The heat dissipation member 670 may be electrically insulated from the redistribution layer 601 of the semiconductor substrate 600.

The heat dissipation member 670 may include first heat dissipation portions 670-H1 and 670-H2 overlapping respective high-temperature areas H1 and H2 of the image sensor chip 610, and a second heat dissipation portion surrounding the first heat dissipation portions. For example, the heat dissipation member 670 may include a first-first heat dissipation portion 670-H1 overlapping with the first high-temperature area H1 and a first-second heat dissipation portion 670-H2 overlapping with the second high-temperature area H2. The heat dissipation member 670 may perform a heat dissipation function by dispersing heat received from the high-temperature areas H1 and H2 of the image sensor chip 610 through the respective first heat dissipation portions 670-H1 and 670-H2 to the second heat dissipation portion. Since the heat dissipation member 670 is formed with an area overlapping with the entire image sensing area A1 of the image sensor chip 610, the temperature deviation of a portion of the semiconductor substrate 600 corresponding to the entire image sensing area A1 may be reduced through the heat dissipation member 670.

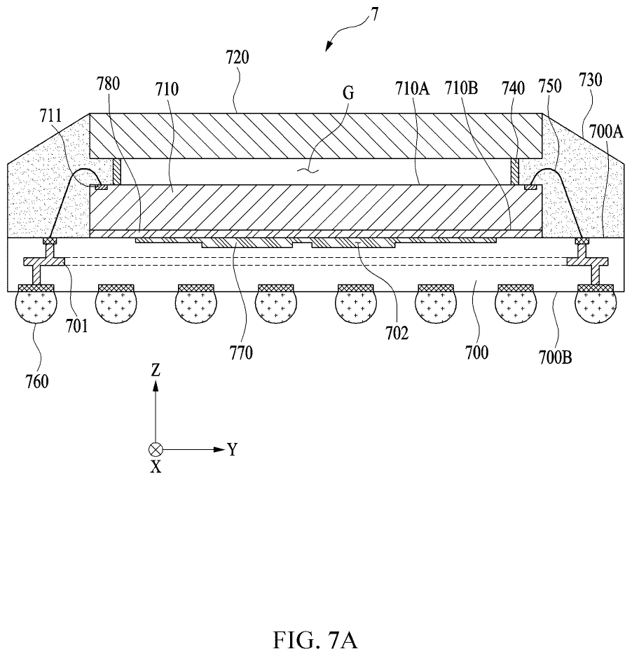

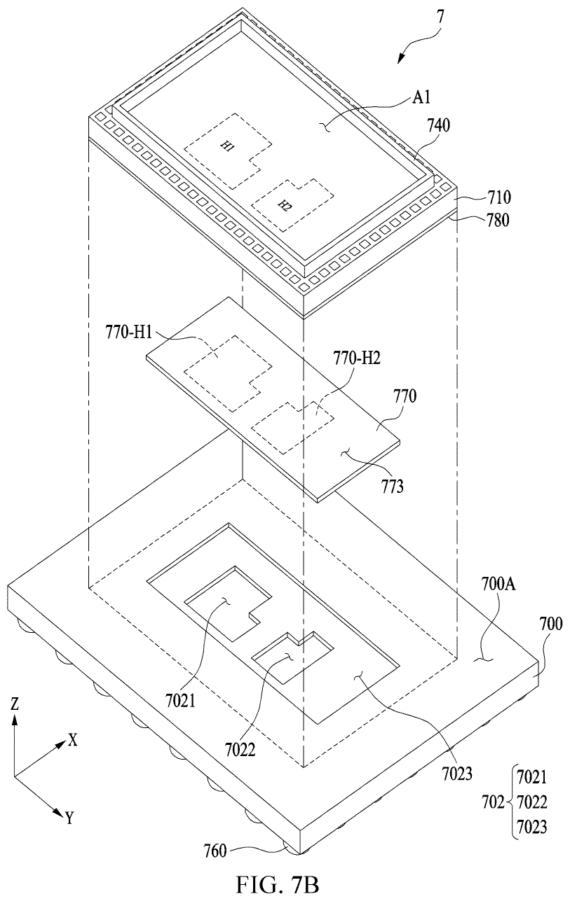

FIG. 7A is a cross-sectional view of a semiconductor package according to an embodiment. FIG. 7B is an exploded perspective view of the semiconductor package according to an embodiment.

Referring to FIGS. 7A and 7B, a semiconductor package 7 may include a semiconductor substrate 700 including a redistribution layer 701, an image sensor chip 710 arranged on a first substrate surface 700A of the semiconductor substrate 700, a conductive wire 750 electrically connecting the image sensor chip 710 and the redistribution layer 701 of the semiconductor substrate 700, a cover glass 720 arranged to cover an upper portion of the image sensor chip 710, a bonding dam 740 forming a gap between the image sensor chip 710 and the cover glass 720 and connecting the image sensor chip 710 and the cover glass 720, a molding member 730 surrounding the image sensor chip 710, a plurality of connecting terminals 760 arranged on a second substrate surface 700B of the semiconductor substrate 700, and a heat dissipation member 770.

The semiconductor substrate 700 may include the first substrate surface 700A and the second substrate surface 700B opposite to the first substrate surface 700A. The plurality of connecting terminals 760 may be arranged on the second substrate surface 700B to be electrically connected to the redistribution layer 701 through the second connection pads 7012.

The image sensor chip 710 may include a first surface 710A and a second surface 710B opposite to the first surface 710A. The image sensor chip 710 may be arranged so that the second surface 710B may face the first substrate surface 700A of the semiconductor substrate 700. A bonding member 780 may be arranged between the semiconductor substrate 700 and the image sensor chip 710. A chip pad 711 positioned outside the edges of the bonding dam 740 and connected with the conductive wire 750 may be arranged on the first surface 710A of the image sensor chip 710.

A plurality of high-temperature areas H1 and H2 may be defined in the image sensor chip 710. For example, a first high-temperature area H1 and a second high-temperature area H2 may be defined in the image sensor chip 710. The first high-temperature area H1 and the second high-temperature area H2 may be arranged to overlap within the image sensing area A1 of the image sensor chip 710. The first high-temperature area H1 may generate more heat than the second high-temperature area H2.

A recess 702 may be defined on the first substrate surface 700A of the semiconductor substrate 700. The heat dissipation member 770 may be seated in the recess 702. The recess 702 and the heat dissipation member 770 may be formed with an area overlapping with the entire image sensing area A1 of the image sensor chip 710. For example, in a state in which the first surface 710A of the image sensor chip 710 is viewed, the heat dissipation member 770 may overlap with the entire image sensing area A1 of the image sensor chip 710. When the heat dissipation member 770 is embedded in the first substrate surface 700A, the surface thereof may be co-planar with the surrounding area of the first substrate surface 700A. The heat dissipation member 770 may be electrically insulated from the redistribution layer 701 of the semiconductor substrate 700.

The heat dissipation member 770 may include first heat dissipation portions 770-H1 and 770-H2 overlapping respective high-temperature areas H1 and H2 of the image sensor chip 710, and a second heat dissipation portion 773 surrounding the first heat dissipation portions 770-H1 and 770-H2. For example, the heat dissipation member 770 may include a first-first heat dissipation portion 770-H1 overlapping with the first high-temperature area H1 and a first-second heat dissipation portion 770-H2 overlapping with the second high-temperature area H2. The heat dissipation member 770 may perform a heat dissipation function by dispersing heat received from the high-temperature areas of the image sensor chip 710 through the respective first heat dissipation portions 770-H1 and 770-H2 to the second heat dissipation portion 773.

The second heat dissipation portion 773 may be formed to have a smaller thickness than the first heat dissipation portions 770-H1 and 770-H2. For example, the first heat dissipation portions 770-H1 and 770-H2 may be formed to have a first thickness, and the second heat dissipation portion 773 may be formed to have a second thickness smaller than the first thickness. Since the heat dissipation performance improves as the thickness of a heat dissipation member 770 increases, forming the first heat dissipation portions 770-H1 and 770-H2 of the heat dissipation member 770 overlapping high-temperature areas to be thicker than the second heat dissipation portion 773 may improve heat dissipation performance of the heat dissipation member 770 on the semiconductor substrate 700. At the same time, forming the second heat dissipation portion 773 to be thinner than the first heat dissipation portions 770-H1 and 770-H2 may reduce the space to form the recess 702 required when installing the heat dissipation member 770 on the semiconductor substrate 700.

Although not shown in the drawing, the first-first heat dissipation portion 770-H1 and the first-second heat dissipation portion 770-H2 may be formed to have different thicknesses. For example, when the first high-temperature portion H1 of the image sensor chip 710 generates more heat than the second high-temperature portion H2, the first-first heat dissipation portion 770-H1 may be formed to have a greater thickness than the first-second heat dissipation portion 770-H2.

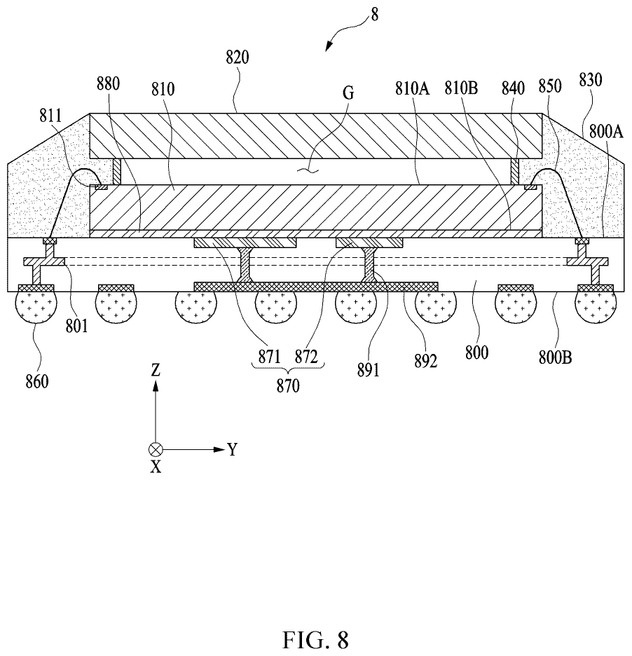

FIG. 8 is a cross-sectional view of a semiconductor package 8 according to an embodiment.

Referring to FIG. 8, a semiconductor package 8 may include a semiconductor substrate 800 including a redistribution layer 801, an image sensor chip 810 arranged on a first substrate surface 800A of the semiconductor substrate 800, a conductive wire 850 electrically connecting the image sensor chip 810 and the redistribution layer 801 of the semiconductor substrate 800, a cover glass 820 arranged to cover an upper portion of the image sensor chip 810, a bonding dam 840 forming a gap between the image sensor chip 810 and the cover glass 820 and connecting the image sensor chip 810 and the cover glass 820, a molding member 830 surrounding the image sensor chip 810, a plurality of connecting terminals 860 arranged on a second substrate surface 800B of the semiconductor substrate 800, one or more heat dissipation members 870, a lower heat dissipation member 892, and thermally conductive vias 891.

The semiconductor substrate 800 may include the first substrate surface 800A and the second substrate surface 800B opposite to the first substrate surface 800A. The plurality of connecting terminals 860 may be arranged on the second substrate surface 800B to be electrically connected to the redistribution layer 801 through the second connection pads 8012.

The image sensor chip 810 may include a first surface 810A and a second surface 810B opposite to the first surface 810A. The image sensor chip 810 may be arranged so that the second surface 810B may face the first substrate surface 800A of the semiconductor substrate 800. A bonding member 880 may be arranged between the semiconductor substrate 800 and the image sensor chip 810. A chip pad 811 positioned outside the edges of the bonding dam 840 and connected with the conductive wire 850 may be arranged on the first surface 810A of the image sensor chip 810.

The heat dissipation members 870 may be arranged on the semiconductor substrate 800. For example, a plurality of recesses 802 may be defined on the first substrate surface 800A of the semiconductor substrate 800, and the heat dissipation members 870 may be arranged in the plurality of recesses 802, respectively. For example, a first heat dissipation member 871 and a second heat dissipation member 872 may be embedded in the first substrate surface 800A of the semiconductor substrate 800. When the heat dissipation members 870 are embedded in the first substrate surface 800A, the surfaces thereof may be co-planar with the surrounding area of the first substrate surface 800A. The heat dissipation members 870 may be electrically insulated from the redistribution layer 801 of the semiconductor substrate 800.

The heat dissipation members 870 may overlap with high-temperature areas that generate relatively much heat in the image sensor chip 810. The heat dissipation members 870 may function to receive heat generated from the high-temperature areas of the image sensor chip 810 and disperse the heat to the surrounding area of the semiconductor substrate 800.

The lower heat dissipation member 892 may be arranged on the second substrate surface 800B of the semiconductor substrate 800. The lower heat dissipation member 892 may be electrically insulated from the redistribution layer 801 of the semiconductor substrate 800. For example, the semiconductor package 8 may be formed in a structure in which the connecting terminals 860 are omitted from a portion of the second substrate surface 800B corresponding to an image sensing area of the image sensor chip 810. The lower heat dissipation member 892 may be arranged on the portion of the second substrate surface 800B from which the connecting terminals 860 are omitted.

The thermally conductive vias 891 may connect the respective heat dissipation members 870 arranged on the first substrate surface 800A to the lower heat dissipation member 892 arranged on the second substrate surface 800B. The thermally conductive vias 891 may form direct heat transmission paths from the heat dissipation members 870 arranged on the first substrate surface 800A to the lower heat dissipation member 892. The thermally conductive vias 891 may be arranged to be electrically insulated from the redistribution layer 801 formed on the semiconductor substrate 800. Accordingly, a short circuit in the semiconductor package 8 caused by the thermally conductive vias 891 may be prevented.

The semiconductor package 8 may transfer heat generated in the image sensor chip 810 from the first substrate surface 800A to the second substrate surface 800B of the semiconductor substrate 800 through the heat dissipation members 870, the thermally conductive vias 891, and the lower heat dissipation member 892. Accordingly, the heat transferred from the image sensor chip 810 to the semiconductor substrate 800 may be effectively dispersed and dissipated to the outside of the semiconductor package 8. Accordingly, the temperature deviation between portions of the semiconductor substrate 800 in the semiconductor package 8 may be reduced, and the heat dissipation performance of the semiconductor package 8 may improve.

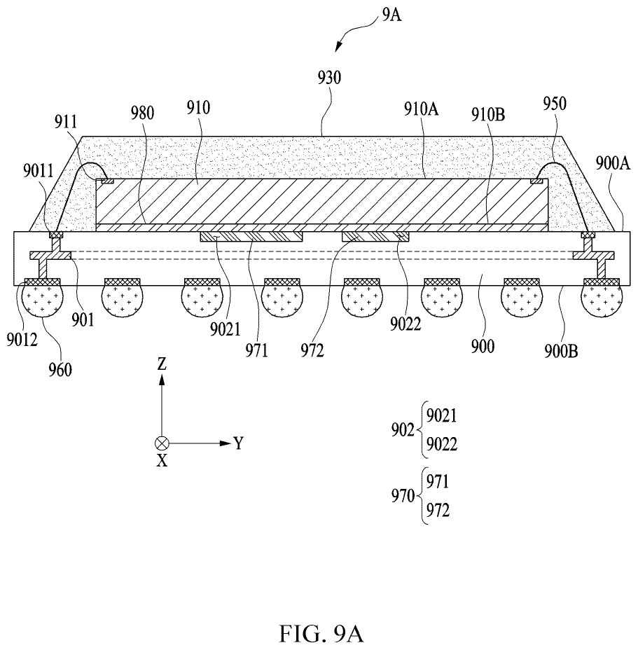

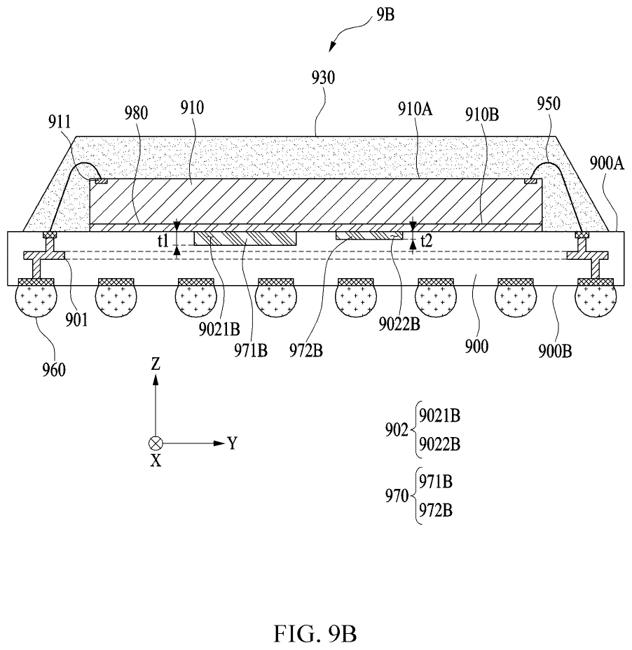

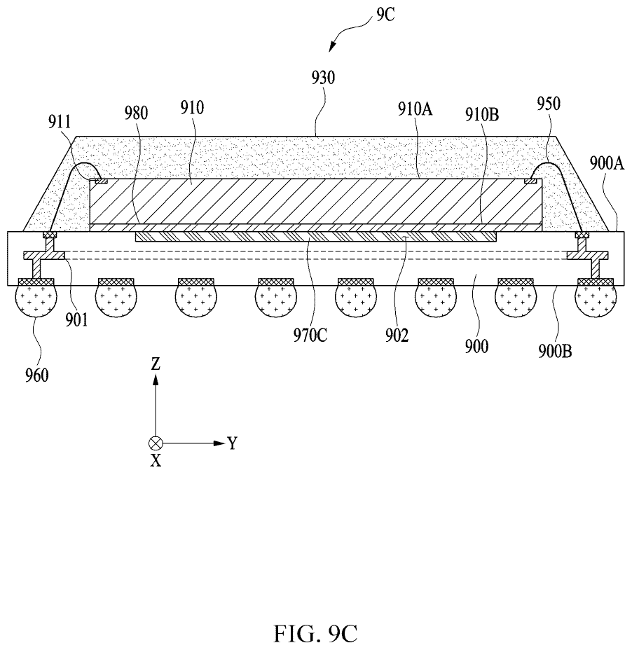

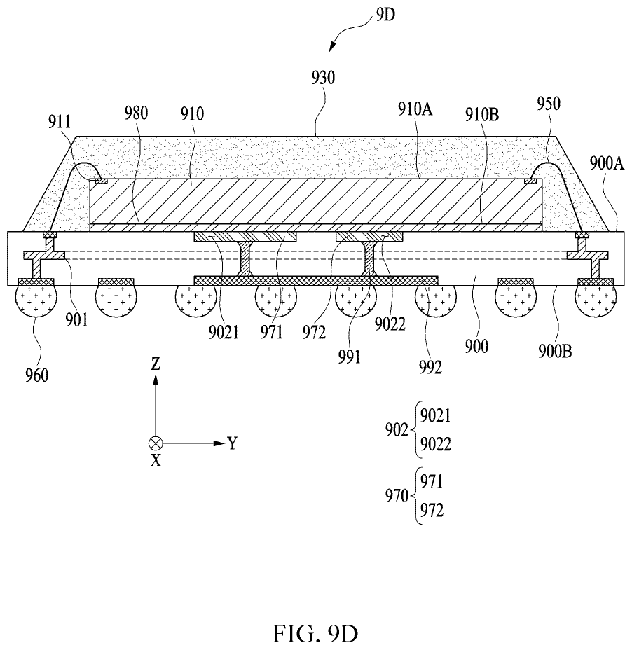

FIG. 9A is a cross-sectional view of a semiconductor package according to an embodiment. FIG. 9B is a cross-sectional view of a semiconductor package according to an embodiment. FIG. 9C is a cross-sectional view of a semiconductor package according to an embodiment. FIG. 9D is a cross-sectional view of a semiconductor package according to an embodiment.

Hereinafter, semiconductor packages according to various examples will be described with reference to FIGS. 9A to 9D. In describing the exemplary semiconductor packages through FIGS. 9A to 9D, terms that are the same as those mentioned above may be understood as being used for the same or similar components unless otherwise stated. Even if not mentioned through a specific example, it should be noted that the structures of the heat dissipation members applied to the previously described embodiments may be applied in the same or similar manners.

Referring to FIG. 9A, a semiconductor package 9A may include a semiconductor substrate 900 including a redistribution layer 901, a semiconductor chip 910 arranged on the semiconductor substrate 900, a conductive wire 950 electrically connecting the semiconductor chip 910 to the redistribution layer 901 of the semiconductor substrate 900, a molding member 930 surrounding the semiconductor chip 910, heat dissipation members 970 arranged on the semiconductor substrate 900 to form heat conduction paths between the semiconductor substrate 900 and the semiconductor chip 910, and a plurality of connecting terminals 960 arranged on a lower portion of the semiconductor substrate 900. For example, the semiconductor package 9 may be a BGA in which the connecting terminals 960 are formed as solder balls.

The semiconductor substrate 900 may include a first substrate surface 900A on which the semiconductor chip 910 is arranged, and a second substrate surface 900B opposite to the first substrate surface 900A. The redistribution layer 901 may be formed on the semiconductor substrate 900. The redistribution layer 901 may form an electrical path extending from the first substrate surface 900A to the second substrate surface 900B of the semiconductor substrate 900. A plurality of first connection pads 9011 to which conductive wires 950 are connected may be arranged on the first substrate surface 900A of the semiconductor substrate 900, and a plurality of second connection pads 9012 to which the connecting terminals 960 are connected may be arranged on the second substrate surface 900B of the semiconductor substrate 900. The plurality of first connection pads 9011 may be arranged on the edges of the semiconductor substrate 900 to be positioned outside the perimeter of the semiconductor chip 910 arranged on the semiconductor substrate 900.

The semiconductor chip 910 may be attached to the first substrate surface 900A of the semiconductor substrate 900. The semiconductor chip 910 may include a first surface 910A and a second surface 910B opposite to the first surface 910A. The semiconductor chip 910 may be arranged so that the second surface 910B may face the first substrate surface 900A of the semiconductor substrate 900. A plurality of chip pads 911 may be arranged on the first surface 910A of the semiconductor chip 910. The chip pads 911 may be electrically connected to the redistribution layer 901 of the semiconductor substrate 900 through the conductive wires 950. The semiconductor chip 910 may include a plurality of semiconductor devices formed on the first surface 910A being an active surface. The semiconductor devices may include various micro-electronic devices such as, for example, a metal-oxide-semiconductor field-effect transistor (MOSFET) such as a complementary metal-insulator-semiconductor transistor (CMOS transistor), a system large-scale integration (LSI), an active device, a passive device, and the like. The plurality of semiconductor devices may be electrically separated from each other by an insulating film.

A bonding member 980 may be arranged between the semiconductor substrate 900 and the semiconductor chip 910. The bonding member 980 may be formed between the first substrate surface 900A of the semiconductor substrate 900 and the second surface 910B of the semiconductor chip 910 and may bond the semiconductor chip 910 to the semiconductor substrate 900. The bonding member 980 may be formed by a bonding material applied to the first substrate surface 900A of the semiconductor substrate 900 during the process of manufacturing the semiconductor package 9.

The molding member 930 may be arranged on the semiconductor substrate 900 and may surround the semiconductor chip 910 to protect the semiconductor chip 910. The molding member 930 may cover the edges of the first substrate surface 900A of the semiconductor substrate 900. Since the conductive wire 950 is surrounded by the molding member 930, the connection structure of the semiconductor chip 910 and the semiconductor substrate 900 through the conductive wire 950 may be maintained more firmly.

The connecting terminals 960 may be connected to the second substrate surface 900B of the semiconductor substrate 900. The connecting terminals 960 may be, for example, soldered to the second connection pads 9012 exposed on the second substrate surface 900B of the semiconductor substrate 900 and electrically connected to the redistribution layer 901.

The heat dissipation members 970 may be arranged on the semiconductor substrate 900. The heat dissipation members 970 may be embedded to be positioned in the first substrate surface 900A of the semiconductor substrate 900. For example, one or more recesses 902 may be defined on the first substrate surface 900A of the semiconductor substrate 900, and the heat dissipation members 970 may be seated in the respective recesses 902. For example, a first recess 9021 in which a first heat dissipation member 971 is arranged and a second recess 9022 in which a second heat dissipation member 972 is arranged may be formed on the first substrate surface 900A of the semiconductor substrate 900. In a state in which the respective heat dissipation members 970 are arranged in the recesses 902, the surfaces of the heat dissipation members 970 facing the semiconductor chip 910 may be co-planar with the first substrate surface 900A of the semiconductor substrate 900.

The heat dissipation members 970 may be arranged to overlap with areas that generate relatively much heat in the semiconductor chip 910. For example, portions of the semiconductor chip 910 overlapping with the heat dissipation members 970 may generate more heat than a portion of the semiconductor chip 910 non-overlapping with the heat dissipation members 970. The heat dissipation members 970 may form heat conduction paths between the semiconductor chip 910 and the semiconductor substrate 900, thereby improving the effect of heat dissipation from the semiconductor chip 910 to the semiconductor substrate 900.

The heat dissipation members 970 may be formed of a material having high thermal conductivity. For example, the heat dissipation members 970 may be formed of a material having a higher thermal conductivity than a non-metallic portion (e.g., polyimide (PI)) of the semiconductor substrate 900. The heat dissipation members 970 may be formed of a metal material having high thermal conductivity, for example, copper (Cu), aluminum (Al), silver (Au), zinc (Zn), tungsten, magnesium (Mg), molybdenum, an aluminum alloy, or a combination thereof. In another example, the heat dissipation members 970 may be formed of a graphite material having high thermal conductivity. In still another example, the heat dissipation members 970 may be formed of a non-conductive material. For example, the heat dissipation members 970 may be formed of a synthetic resin including a thermally conductive filler. However, the materials of the heat dissipation members 970 described above are merely examples, and the material of the heat dissipation member 970 is not limited to the materials mentioned above.

The heat dissipation members 970 may be electrically insulated from the redistribution layer 901 of the semiconductor substrate 900. Therefore, when the semiconductor chip 910 comes into contact with the heat dissipation members 970, electrical paths between the semiconductor substrate 900 and the semiconductor chip 910 through the heat dissipation members 970 may not be formed. Therefore, when the heat dissipation members 970 is formed of a conductive material, a short circuit in the semiconductor package 9 caused by the heat dissipation members 970 may be prevented.

Referring to FIG. 9B, a semiconductor package 9B may include a semiconductor substrate 900 including a redistribution layer 901, a semiconductor chip 910 arranged on a first substrate surface 900A of the semiconductor substrate 900, a conductive wire 950 electrically connecting the semiconductor chip 910 to the redistribution layer 901 of the semiconductor substrate 900, a molding member 930 surrounding the semiconductor chip 910, a plurality of connecting terminals 960 arranged on a second substrate surface 900B of the semiconductor substrate 900, and heat dissipation members 970 arranged on the semiconductor substrate 900 to form heat conduction paths between the semiconductor substrate 900 and the semiconductor chip 910.

The semiconductor chip 910 may include a first surface 910A and a second surface 910B opposite to the first surface 910A. The semiconductor chip 910 may be arranged so that the second surface 910B may face the first substrate surface 900A of the semiconductor substrate 900. A bonding member 980 may be arranged between the semiconductor substrate 900 and the semiconductor chip 910. Chip pads 911 to which the conductive wires 950 are connected may be arranged on the first surface 910A of the semiconductor chip 910.

The heat dissipation members 970 may be arranged on the semiconductor substrate 900. The heat dissipation members 970 may be embedded to be positioned in the first substrate surface 900A of the semiconductor substrate 900. For example, a first recess 9021B and a second recess 9022B may be defined separately on the first substrate surface 900A, and a first heat dissipation member 971B and a second heat dissipation member 972B may be arranged in the first recess 9021B and the second recess 9022B, respectively. In a state in which the respective heat dissipation members 971B and 972B are arranged in the recesses 902, the surfaces of the heat dissipation members 970 facing the semiconductor chip 910 may be co-planar with the first substrate surface 900A of the semiconductor substrate 900. Each of the heat dissipation members 970 may be electrically insulated from the redistribution layer 901 of the semiconductor substrate 900. Portions of the semiconductor chip 910 overlapping with the plurality of heat dissipation members 970 arranged on the semiconductor substrate 900 may generate more heat than a portion non-overlapping with the heat dissipation members 970.

The plurality of heat dissipation members 970 arranged on the semiconductor substrate 900 may be formed to have different thicknesses. For example, the first heat dissipation member 971B may be formed to have a first thickness t1, and the second heat dissipation member 972B may be formed to have a second thickness t2 smaller than the first thickness t1. In this case, a portion of the semiconductor chip 910 overlapping with the first heat dissipation member 971B may generate more heat than a portion of the semiconductor chip 910 overlapping with the second heat dissipation member 972B. Since the heat dissipation performance improves as the thickness of a heat dissipation member 970 increases, the first heat dissipation member 971B may have higher heat dissipation performance than the second heat dissipation member 972B. When the first high-temperature area H1 generates more heat than the second high-temperature area H2, forming the first heat dissipation member 971B to be thicker than the second heat dissipation member 972B may allow more effective dissipation of the heat generated in the first high-temperature area H1. In addition, forming the second heat dissipation member 972B to be thinner than the first heat dissipation member 971B may minimize the space to form the recesses 902 required when installing the heat dissipation members 970 on the semiconductor substrate 900.

Referring to FIG. 9C, a semiconductor package 9C may include a semiconductor substrate 900 including a redistribution layer 901, a semiconductor chip 910 arranged on a first substrate surface 900A of the semiconductor substrate 900, a conductive wire 950 electrically connecting the semiconductor chip 910 to the redistribution layer 901 of the semiconductor substrate 900, a molding member 930 surrounding the semiconductor chip 910, a plurality of connecting terminals 960 arranged on a second substrate surface 900B of the semiconductor substrate 900, a heat dissipation member 970C arranged on the semiconductor substrate 900 to form a heat conduction path between the semiconductor substrate 900 and the semiconductor chip 910.

The semiconductor chip 910 may include a first surface 910A and a second surface 910B opposite to the first surface 910A. The semiconductor chip 910 may be arranged so that the second surface 910B may face the first substrate surface 900A of the semiconductor substrate 900. A bonding member 980 may be arranged between the semiconductor substrate 900 and the semiconductor chip 910. Chip pads 911 to which the conductive wires 950 are connected may be arranged on the first surface 910A of the semiconductor chip 910.

The heat dissipation member 970C may be arranged on the semiconductor substrate 900. The heat dissipation members 970 may be embedded to be positioned in the first substrate surface 900A of the semiconductor substrate 900. For example, a recess 902 may be defined on the first substrate surface 900A, and the heat dissipation member 970C may be arranged in the recess 902. In a state in which the heat dissipation member 970 is arranged in the recess 902, the surface of the heat dissipation member 970 facing the semiconductor chip 910 may be co-planar with the first substrate surface 900A of the semiconductor substrate 900. The heat dissipation member 970C may be electrically insulated from the redistribution layer 901 of the semiconductor substrate 900.

The heat dissipation member 970C may be formed with an area overlapping with most of the area of the semiconductor chip 910 except for the edges where the chip pads 911 are positioned, when the first surface 910A of the semiconductor chip 910 is viewed. In this case, the heat dissipation member 970C may receive heat generated in a portion of the semiconductor chip 910 that generates relatively much heat and disperse the heat to the surrounding area, thereby evenly dispersing heat in the entire area in which the heat dissipation member 970C is arranged. Accordingly, the temperature deviation between portions of the semiconductor substrate 900 corresponding to the semiconductor chip 910 may be reduced.

Referring to FIG. 9D, a semiconductor package 9D may include a semiconductor substrate 900 including a redistribution layer 901, a semiconductor chip 910 arranged on a first substrate surface 900A of the semiconductor substrate 900, a conductive wire 950 electrically connecting the semiconductor chip 910 to the redistribution layer 901 of the semiconductor substrate 900, a molding member 930 surrounding the semiconductor chip 910, a plurality of connecting terminals 960 arranged on a second substrate surface 900B of the semiconductor substrate 900, heat dissipation members 970 arranged on the semiconductor substrate 900 to form heat conduction paths between the semiconductor substrate 900 and the semiconductor chip 910, a lower heat dissipation member 992 arranged on the second substrate surface 900B of the semiconductor substrate 900, and thermally conductive vias 991 forming heat conduction paths between the heat dissipation members 970 and the lower heat dissipation member 992.

The semiconductor chip 910 may include a first surface 910A and a second surface 910B opposite to the first surface 910A. The semiconductor chip 910 may be arranged so that the second surface 910B may face the first substrate surface 900A of the semiconductor substrate 900. A bonding member 980 may be arranged between the semiconductor substrate 900 and the semiconductor chip 910. Chip pads 911 to which the conductive wires 950 are connected may be arranged on the first surface 910A of the semiconductor chip 910.

The heat dissipation members 970 may be arranged on the semiconductor substrate 900. The heat dissipation members 970 may be embedded to be positioned in the first substrate surface 900A of the semiconductor substrate 900. For example, a first recess 9021 and a second recess 9022 may be defined separately on the first substrate surface 900A, and a first heat dissipation member 971 and a second heat dissipation member 972 may be arranged in the first recess 9021 and the second recess 9022, respectively. In a state in which the respective heat dissipation members 970 are arranged in the recesses 902, the surfaces of the heat dissipation members 970 facing the semiconductor chip 910 may be co-planar with the first substrate surface 900A of the semiconductor substrate 900. Each of the heat dissipation members 970 may be electrically insulated from the redistribution layer 901 of the semiconductor substrate 900. Portions of the semiconductor chip 910 overlapping with the plurality of heat dissipation members 970 arranged on the semiconductor substrate 900 may generate more heat than a portion non-overlapping with the heat dissipation members 970. The heat dissipation members 970 may function to receive heat generated from the high-temperature areas of the semiconductor chip 910 and disperse the heat to the surrounding area of the semiconductor substrate 900.

The lower heat dissipation member 992 may be arranged on the second substrate surface 900B of the semiconductor substrate 900. The lower heat dissipation member 992 may be electrically insulated from the redistribution layer 901 of the semiconductor substrate 900. For example, the semiconductor package 9 may be formed in a structure in which the connecting terminals 960 are omitted from a portion of the second substrate surface 900B corresponding to the semiconductor chip 910. The lower heat dissipation member 992 may be arranged on the portion of the second substrate surface 900B from which the connecting terminals 960 are omitted.

The thermally conductive vias 991 may connect the respective heat dissipation members 970 arranged on the first substrate surface 900A to the lower heat dissipation member 992 arranged on the second substrate surface 900B. The thermally conductive vias 991 may form direct heat transmission paths from the heat dissipation members 970 arranged on the first substrate surface 900A to the lower heat dissipation member 992. The thermally conductive vias 991 may be arranged to be electrically insulated from the redistribution layer 901 formed on the semiconductor substrate 900. Accordingly, a short circuit in the semiconductor package 9D caused by the thermally conductive vias 991 may be prevented.

A number of embodiments have been described above. Nevertheless, it should be understood that various modifications and variations may be made to these embodiments. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and/or equivalents of the claims are within the scope of the following claims.

What is claimed is:

1. A semiconductor package comprising:
a semiconductor substrate having a first substrate surface defining one or more recesses;
an image sensor chip arranged on the first substrate surface of the semiconductor substrate, the image sensor chip comprising an image sensing area and a non-sensing area;
a cover glass facing an upper portion of the image sensor chip;
a bonding dam surrounding the image sensing area and positioned between the image sensor chip and the cover glass; and
one or more heat dissipation members arranged in the one or more recesses.

2. The semiconductor package of claim 1, wherein the one or more heat dissipation members overlap with the image sensing area of the image sensor chip.

3. The semiconductor package of claim 1, wherein upper surfaces of the one or more heat dissipation members are co-planar with the first substrate surface of the semiconductor substrate.

4. The semiconductor package of claim 1, wherein:
the image sensing area comprises one or more high-temperature areas configured to generate more heat than a remaining area are defined in the image sensor chip, and
the one or more high-temperature areas overlap with the one or more heat dissipation members.

5. The semiconductor package of claim 1, wherein the one or more dissipation members are in contact with a lower portion of the image sensor chip that is opposite to the upper portion.

6. The semiconductor package of claim 1, wherein the one or more heat dissipation members comprise a plurality of heat dissipation members having a same thickness.

7. The semiconductor package of claim 4, wherein:
the image sensing area further comprises one or more low-temperature areas configured to generate less heat than a remaining area are defined in the image sensor chip, and
at least one of the one or more high-temperature areas and at least one of the one or more low-temperature areas overlap with one heat dissipation member.

8. The semiconductor package of claim 4, wherein the one or more heat dissipation members comprise:
a first heat dissipation member arranged to overlap with a first high-temperature area of the one or more high-temperature areas; and
a second heat dissipation member arranged to overlap with a second high-temperature area of the one or more high-temperature areas, the second heat dissipation member having a smaller thickness than the first heat dissipation member,
wherein the first high-temperature area generates more heat than the second high-temperature area.

9. The semiconductor package of claim 1, wherein the one or more heat dissipation members comprise:
a first heat dissipation portion having a first thickness; and
a second heat dissipation portion having a second thickness smaller than the first thickness.

10. The semiconductor package of claim 9, wherein a portion of the image sensor chip overlapping with the first heat dissipation portion generates more heat than a portion of the image sensor chip overlapping with the second heat dissipation portion.

11. The semiconductor package of claim 10, wherein the second heat dissipation portion surrounds the first heat dissipation portion.

12. The semiconductor package of claim 1, wherein:
at least one heat dissipation member of the one or more heat dissipation members is arranged on the semiconductor substrate, and
the at least one heat dissipation member extends over an area that overlaps with the entire image sensing area of the image sensor chip.

13. The semiconductor package of claim 12, wherein the at least one heat dissipation member comprises:
one or more first heat dissipation portions having a first thickness; and
a second heat dissipation portion having a second thickness smaller than the first thickness,
wherein a portion of the image sensor chip overlapping with the first heat dissipation portion generates more heat than a remaining area defined in the image sensor chip.

14. The semiconductor package of claim 1, further comprising:
a redistribution layer formed in the semiconductor substrate; and
a conductive wire connecting the image sensor chip to the redistribution layer of the semiconductor substrate,
wherein the one or more heat dissipation members are electrically insulated from the redistribution layer of the semiconductor substrate.

15. The semiconductor package of claim 1, further comprising:
a lower heat dissipation member arranged on a second substrate surface, opposite to the first substrate surface, of the semiconductor substrate; and
a thermally conductive via extending through the semiconductor substrate and connecting the one or more heat dissipation members to the lower heat dissipation member.

16. A semiconductor package comprising:
a semiconductor substrate on which a redistribution layer is formed, the semiconductor substrate having a first substrate surface defining one or more recesses;
a semiconductor chip arranged on the first substrate surface of the semiconductor substrate, the semiconductor chip comprising a first surface opposite to the semiconductor substrate and a second surface opposite to the first surface;
a conductive wire connected to the second surface of the semiconductor chip, the conductive wire electrically connecting the semiconductor chip to the redistribution layer of the semiconductor substrate;
a molding member surrounding the semiconductor chip; and
a first heat dissipation member arranged in the one or more recesses, the first heat dissipation member forming a heat conduction path between the semiconductor chip and the semiconductor substrate.

17. The semiconductor package of claim 16, wherein
a portion of the semiconductor chip overlapping with the first heat dissipation member generates more heat than a portion of the semiconductor chip non-overlapping with the first heat dissipation member.

18. The semiconductor package of claim 16, further comprising a second heat dissipation member arranged in the one or more recesses, wherein:
the first heat dissipation member has a first thickness, and
the second heat dissipation member has a second thickness smaller than the first thickness,
wherein a portion of the semiconductor chip overlapping with the first heat dissipation member generates more heat than a portion of the semiconductor chip overlapping with the second heat dissipation member.

19. The semiconductor package of claim 16, wherein:
an upper surface of the first heat dissipation member is co-planar with the first substrate surface of the semiconductor substrate, and
the first heat dissipation member is electrically insulated from the redistribution layer of the semiconductor substrate.

20. The semiconductor package of claim 16, further comprising:
a lower heat dissipation member arranged on a second substrate surface, opposite to the first substrate surface, of the semiconductor substrate; and
a thermally conductive via extending through the semiconductor substrate and connecting the one or more heat dissipation members to the lower heat dissipation member.
